(19) United States
(12) Patent Application Publication
(10) Pub. No.: US 2026/0202452 A1
(43) Pub. Date: Jul. 16, 2026

(54) LOW-AMPLITUDE DIRECT LIGHTNING HAZARD ASSESSMENT AND WARNING METHOD FOR DISTRIBUTION NETWORK

(71) Applicant: Kunming University of Science and Technology, Kunming (CN)

(72) Inventors: Hongchun SHU, Kunming (CN); Yutao TANG, Kunming (CN); Kai HE, Kunming (CN); Weijie LOU, Kunming (CN); Yiming HAN, Kunming (CN); Yue DAI, Kunming (CN)

(73) Assignee: Kunming University of Science and Technology, Kunming (CN)

(21) Appl. No.: 19/062,071

(22) Filed: Feb. 25, 2025

(30) Foreign Application Priority Data
Jan. 13, 2025 (CN) 202510049856.6

(51) Int. Cl. G01R 27/20; G01B 21/08; G01R 19/165; G06F 17/10

(52) U.S. Cl. CPC G01R 27/20; G01B 21/08; G01R 19/16533; G06F 17/10

(57) ABSTRACT

A low-amplitude direct lightning hazard assessment and warning method for a distribution network includes: calculating a maximum grounding resistance, nominal height, and tower span of each line in the distribution network, counting insulator models and lightning impulse withstand voltage Uₛₑₜ for each line in the distribution network, calculating grounding shunt coefficient β of each tower, and inputting these values into a distribution network lightning detection system; the distribution network lightning detection system detects cloud-to-ground lightning in real time and calculates the overvoltage U of direct lightning; if U≥Uₛₑₜ, the hazard is serious, and the system issues a warning; if U<Uₛₑₜ, the hazard is small and no warning is required. Numerous case studies from actual measured data in distribution networks indicate that this method is effective and reliable, improving daily work of operation and maintenance personnel, and is suitable for evaluating hazards of low-amplitude lightning-induced overvoltage in distribution networks.

### CROSS REFERENCE TO THE RELATED APPLICATIONS

This application is based upon and claims priority to Chinese Patent Application No. 202510049856.6, filed on Jan. 13, 2025, the entire contents of which are incorporated herein by reference.

### TECHNICAL FIELD

The present invention relates to a low-amplitude direct lightning hazard assessment and warning method for a distribution network, belonging to the field of power systems protection and control.

### BACKGROUND

Lightning strikes with current amplitudes below 15 kA are classified as low-amplitude lightning, characterized by weak electromagnetic signal strengths, which makes them challenging to detect using conventional lightning location systems. However, in certain regions, newly implemented high-precision distribution network lightning detection systems are capable of detecting these lightning strikes and providing information such as lightning current amplitude and strike location. Occurrence of low-amplitude cloud-to-ground lightning is relatively frequent, and since insulation strength of the distribution network is not high, faults often occur due to such low-amplitude cloud-to-ground lightning. Lightning can cause faults in distribution lines through two primary mechanisms: lightning strikes on the distribution lines, generating direct overvoltage, and induced overvoltage resulting from lightning strikes on the ground and structures near the lines. Compared to induced lightning, direct lightning result a higher surge voltage, which can easily cause damage to transmission lines and power equipment, leading to large-scale power outages. Under the influence of thermal and mechanical forces, physical phenomena such as equipment collapse, deformation, or explosion may also occur. If the overvoltage at the top of a tower caused by a lightning strike exceeds the lightning impulse withstand voltage of the insulator, it can cause insulator flashover, resulting in a short circuit between the line and the ground, which severely threatens the safe operation of the distribution network.

### SUMMARY

Low-amplitude cloud-to-ground lightning represent a major threat to the safe and reliable operation of distribution networks. Currently, the detection of low-amplitude cloud-to-ground lightning mainly relies on manual line inspection, with the assistance of various fault recording data and fault trip information to locate specific information on low-amplitude cloud-to-ground lightning and evaluate their overvoltage hazards. A commonly used method to approximate a maximum overvoltage amplitude of direct lightning strikes on towers is based on regulation formula (1):

$$U = β {R}_{c h} {I}_{L} \qquad ( 1 )$$

The core of this formula is shunt coefficient β, but the regulation rarely mentions the selection of β values for distribution network lines, making it difficult to directly apply this formula for calculation low-amplitude direct lightning overvoltage in distribution networks.

To address the limitations of existing methods for assessing the overvoltage hazards caused by low-amplitude cloud-to-ground lightning in distribution networks, the present invention provides a low-amplitude direct lightning hazard assessment and warning method for a distribution network, the specific steps of which are:

Step 1: counting a maximum grounding resistance R_{ch}, a tower nominal height h and a tower span d of each line in a distribution network, wherein these values are input into corresponding data of each tower in a distribution network lightning detection system;
The “maximum grounding resistance R_{ch}” is determined according to the maximum allowable grounding resistance specified in the grounding network construction regulations for the region. This value is slightly greater than the actual grounding resistance, providing a margin for hazard assessment. The “tower nominal height h” refers to the height from the lowest crossarm of the tower to the ground. The “tower span d” refers to the distance between the current tower and the next tower.

Step 2: counting insulator models and a lightning impulse withstand voltage Uₛₑₜ for each line in the distribution network, wherein these values are input into the corresponding data of each tower in the distribution network lightning detection system;

Step 3: calculating a grounding shunt coefficient β for each tower, wherein this value is input into the corresponding data of each tower in the distribution network lightning detection system;
Among them, the “calculation grounding shunt coefficient β for each tower” is calculated according to the following formula

$${β}_{1} = 3.67 \times 1 {0}^{- 5} {R}_{c h}^{2} - 0.009 {R}_{c h} + 0 \text{.96} \qquad ( 2 )$$

$${β}_{2} = - 7.4 \times 1 {0}^{- 8} {h}^{3} - 7.9 \times 1 {0}^{- 8} {h}^{2} + 2 \times 1 {0}^{- 5} h + 0.9 \; 147 \qquad ( 3 )$$

$${β}_{3} = 2.4 \times 1 {0}^{- 9} {d}^{3} - 3.8 \times 1 {0}^{- 6} {d}^{2} + 2 \times 1 {0}^{- 3} d + 0.5 \; 54 \qquad ( 4 )$$

$$β = {β}_{1} {β}_{2} {β}_{3} \qquad ( 5 )$$

The above formulas (2), (3), and (4) are obtained by fitting experimental data on the relationship between grounding resistance, nominal height, span, and diversion coefficient of different towers. The experimental data curve and fitting curve are shown in FIGS. 2-4, and different fitting methods can also be used for calculation. This step not only addresses the limitations of the value for 8 in distribution network lines, but also integrates the regulation formula with practical scenarios, making the hazard assessment more aligned with actual conditions.

Step 4: detecting, by the distribution network lightning detection system, a cloud-to-ground lightning in real time, wherein if the cloud-to-ground lightning is located at a small distance from a tower, the cloud-to-ground lightning is classified as a direct lightning, and calculating overvoltage U at the top of the tower;
wherein, the “small distance between the cloud-to-ground lightning and the tower” can be determined according to regulations, with a distance greater than 65 meters generally considered as lightning-induced, and the distance of 65 meters or less treated as a direct lightning, though this distance can also be adjusted based on actual conditions; and the calculation of the “calculating overvoltage U at the top of the tower “is based on the following formula:

$$U = β {R}_{c h} {I}_{L} \qquad ( 1 )$$

wherein I_{L} is the lightning current amplitude, which can be obtained from the distribution network lightning detection system; if the line voltage level is high and the tower has a large equivalent inductance, these factors should also be considered in the calculation of formula (1).

Step 5: if U≥Uₛₑₜ, indicating that the overvoltage caused by the cloud-to-ground lightning exceeds the maximum lightning impulse voltage that the insulator can withstand, posing a serious threat to the safety of the line and equipment, and the system issues a warning to remind operation and maintenance personnel to pay close attention to the cloud-to-ground lightning and nearby lines and equipment; if U<Uₛₑₜ, indicating that the cloud-to-ground lightning voltage is within the acceptable range of the insulator, the degree of hazard is low, and no warning is required;
The issuing of a warning is proportional to the degree to which the overvoltage exceeds the lightning impulse withstand voltage.

### The Present Invention Provides the Following Advantageous Effects:

1. By integrating with the distribution network lightning detection system, information on low-amplitude direct lightning, direct lightning overvoltage, and severity of hazard can be obtained through human-machine interaction, significantly enhancing the efficiency of operation and maintenance personnel.
2. The calculation formula for lightning overvoltage in the regulations has been revised by incorporating tower grounding resistance, tower nominal height, and tower span. This not only compensates for the value of the distribution network line shunt coefficient in the regulations, but also adapts the formula to real-world scenarios, thereby improving the accuracy of hazard assessments.
3. It facilitates the observation of patterns of low-amplitude lightning and its associated hazards within the statistical area, providing valuable data support for the intelligent transformation of the distribution network.

### BRIEF DESCRIPTION OF THE DRAWINGS

In order to more clearly explain the examples of the present invention or the technical solutions in the prior art, a brief introduction to the accompanying drawings required for the description of these examples or prior art will be provided. It is evident that the accompanying drawings described below are merely illustrative examples of the present invention, and a person skilled in the art could, without inventive effort, derive other drawings based on these.

FIG. 1 is a flowchart of the method of the present invention;

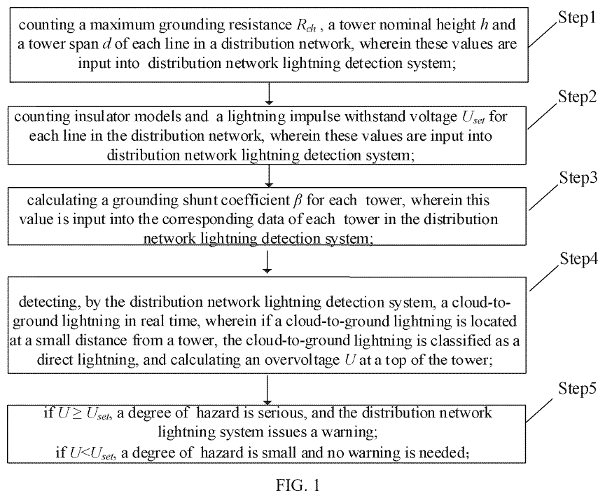

FIG. 2 shows the experimental data curve and fitting curve of β₁;

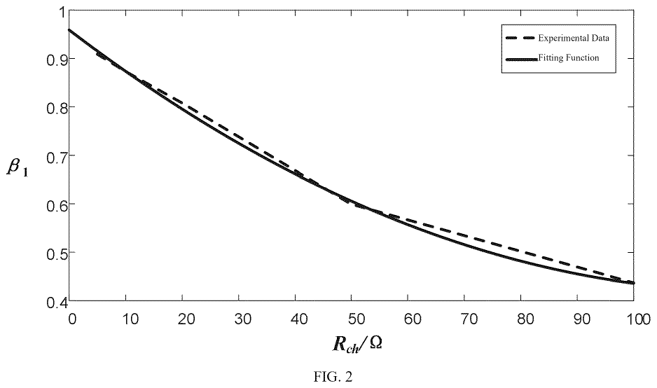

FIG. 3 shows the experimental data curve and fitting curve of β₂;

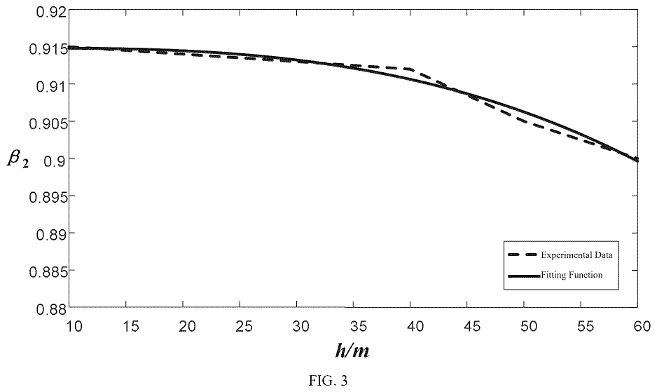

FIG. 4 shows the experimental data curve and fitting curve of β₃.

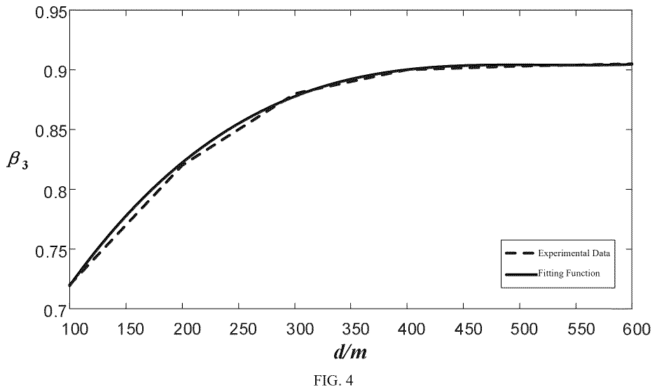

### DETAILED DESCRIPTION OF THE EMBODIMENTS

The present invention will be further explained in conjunction with the accompanying drawings and specific embodiments. Obviously, the described embodiments are only part of the embodiments of the present invention, not all of them. Based on the embodiments of the present invention, all other embodiments that can be derived by a person skilled in the art without inventive effort are within the scope of the present invention's protection.

Example 1: The method of the present invention, “a low-amplitude direct lightning hazard assessment and warning method for a distribution network” is used to analyze to the direct lightning detected by a certain distribution network and make a warning based on its severity of hazard, and the specific implementation steps are as follows:
Step 1: A maximum grounding resistance R_{ch} of a tower of a distribution network line in an area with low soil resistivity is 10Ω, a tower nominal height h is 9 m, and a tower span d is 150 m, wherein these values are input into corresponding data of each tower of the distribution network lightning detection system;
Step 2: A tower insulator model of the line is FPQ3-10/4T20 composite post insulator, with a lightning impulse withstand voltage Uₛₑₜ of 90 kV, wherein these values are input into the corresponding data of each tower in the distribution network lightning detection system;
Step 3: Calculating a grounding shunt coefficient β of each tower, wherein this value is input into the corresponding data of each tower in the distribution network lightning detection system, wherein the calculation process is as follows:

$${β}_{1} = 3.67 \times 1 {0}^{- 5} {R}_{c h}^{2} - 0.009 {R}_{c h} + 0.96 = 0.87$$

$${β}_{2} = - 7.4 \times 1 {0}^{- 8} {h}^{3} - 7.9 \times 1 {0}^{- 8} {h}^{2} + 2 \times 1 {0}^{- 5} h + 0.9147 = 0.915$$

$${β}_{3} = 2.4 \times 1 {0}^{- 9} {d}^{3} - 3.8 \times 1 {0}^{- 6} {d}^{2} + 2 \times 1 {0}^{- 3} d + 0.554 = 0.777$$

$$β = {β}_{1} {β}_{2} {β}_{3} = 0.62$$

Step 4: the distribution network lightning detection system detects cloud-to-ground lightning in real time, wherein a cloud-to-ground lightning hits the tower directly, with a current amplitude of 12 kA, calculating the top overvoltage U=74.4 kV:
Step 5: U<Uₛₑₜ, the degree of hazard is small, and no warning is required;

Example 2: The method of the present invention, “a low-amplitude direct lightning hazard assessment and warning method for distribution networks” is used to analyze to the direct lightning detected by a certain distribution network and make a warning based on its severity of hazard, and the specific implementation steps are as follows:
Step 1: A maximum grounding resistance R_{ch} of a tower of a distribution network line in an area with low soil resistivity is 30Ω, a tower nominal height h is 8 m, and a tower span d is 100 m, wherein these values are input into corresponding data of each tower of the distribution network lightning detection system;
Step 2: A tower insulator model of the line is P-15T stanchion porcelain insulator, with a lightning impulse withstand voltage Uₛₑₜ of 118 kV, wherein these values are input into the corresponding data of each tower in the distribution network lightning detection system;
Step 3: Calculating a grounding shunt coefficient β of each tower, wherein this value is input into the corresponding data of each tower in the distribution network lightning detection system, wherein the calculation process is as follows:

$${β}_{1} = 3.67 \times 1 {0}^{- 5} {R}_{c h}^{2} - 0.009 {R}_{c h} + 0.96 = 0.72$$

$${β}_{2} = - 7.4 \times 1 {0}^{- 8} {h}^{3} - 7.9 \times 1 {0}^{- 8} {h}^{2} + 2 \times 1 {0}^{- 5} h + 0.9147 = 0.914$$

$${β}_{3} = 2.4 \times 1 {0}^{- 9} {d}^{3} - 3.8 \times 1 {0}^{- 6} {d}^{2} + 2 \times 1 {0}^{- 3} d + 0.554 = 0.712$$

$$β = {β}_{1} {β}_{2} {β}_{3} = 0.47$$

Step 4: the distribution network lightning detection system detects cloud-to-ground lightning in real time, wherein a cloud-to-ground lightning hits the tower directly, with a current amplitude of 9 kA, calculating the top overvoltage U=127 kV;
Step 5: U≥Uₛₑₜ, the degree of hazard is serious, and the distribution network lightning detection system issues a warning.

1. A low-amplitude direct lightning hazard assessment and warning method for a distribution network, comprising the following steps:
Step 1: counting a maximum grounding resistance R_{ch}, a tower nominal height h and a tower span d of each line in a distribution network, wherein these values are input into corresponding data of each tower in a distribution network lightning detection system;
Step 2: counting insulator models and a lightning impulse withstand voltage Uₛₑₜ for each line in the distribution network, wherein these values are input into the corresponding data of each tower in the distribution network lightning detection system;
Step 3: calculating a grounding shunt coefficient β for each tower, wherein this value is input into the corresponding data of each tower in the distribution network lightning detection system;
Step 4: detecting, by the distribution network lightning detection system, a cloud-to-ground lightning in real time, wherein if the cloud-to-ground lightning is located at a small distance from a tower, the cloud-to-ground lightning is classified as a direct lightning, and calculating an overvoltage U at a top of the tower; and
Step 5: if U≥Uₛₑₜ, a degree of hazard is serious, and the distribution network lightning detection system issues a warning; if U<Uₛₑₜ, the degree of hazard is small and no warning is needed.

2. The low-amplitude direct lightning hazard assessment and warning method for the distribution network according to claim 1, wherein the maximum grounding resistance R_{ch} of the tower in Step 2 is determined according to a maximum grounding resistance allowed in a local grounding grid construction regulations, wherein R_{ch} is slightly greater than an actual grounding resistance and leaves a certain margin for hazard assessment, wherein the tower nominal height refers to a height from a lowest cross arm of a tower to ground, wherein the tower span d refers to a distance between a current tower and a next tower.

3. The low-amplitude direct lightning hazard assessment and warning method for the distribution network according to claim 1, wherein in Step 3, the grounding shunt coefficient β of each tower is calculated according to the following formula:
$${β}_{1} = 3.67 \times 1 {0}^{- 5} {R}_{c h}^{2} - 0.009 {R}_{c h} + 0 \text{.96} \qquad ( 1 )$$
$${β}_{2} = - 7.4 \times 1 {0}^{- 8} {h}^{3} - 7.9 \times 1 {0}^{- 8} {h}^{2} + 2 \times 1 {0}^{- 5} h + 0.9 \; 147 \qquad ( 2 )$$
$${β}_{3} = 2.4 \times 1 {0}^{- 9} {d}^{3} - 3.8 \times 1 {0}^{- 6} {d}^{2} + 2 \times 1 {0}^{- 3} d + 0.5 \; 54 \qquad ( 3 )$$
$$β = {β}_{1} {β}_{2} {β}_{3} \qquad ( 4 )$$
the above formulas (2), (3), and (4) are all fitted from experimental data on a relationship between different tower grounding resistances, tower nominal heights, tower spans, and shunt coefficients, and are also calculated using different fitting methods.

4. The low-amplitude direct lightning hazard assessment and warning method for the distribution network according to claim 1, wherein the small distance between ground flash and tower in Step 4 is determined according to regulations, wherein a distance greater than 65 m is considered induced lightning, a distance not exceeding 65 m is treated as direct lightning, or this distance is determined according to actual conditions.

5. The low-amplitude direct lightning hazard assessment and warning method for the distribution network according to claim 1, wherein the calculation of calculating the tower top overvoltage U in Step 4 follows the following formula:
$$U = β {R}_{c h} {I}_{L} \qquad ( 5 )$$
wherein, I_{L} is an amplitude of lightning current and is obtained from the distribution network lightning detection system; if a voltage level of a line is high and an equivalent inductance of the tower is large, it needs to be considered in formula (5).

6. The low-amplitude direct lightning hazard assessment and warning method for the distribution network according to claim 1, wherein in Step 5, if U≥Uₛₑₜ, it indicates that the overvoltage caused by the cloud-to-ground lightning exceeds a maximum lightning impulse voltage that an insulator is allowed to withstand, posing a serious threat to the safety of the line and equipment, and the distribution network lightning detection system issues a warning to remind operation and maintenance personnel to pay close attention to the cloud-to-ground lightning and nearby lines and equipment; if U<Uₛₑₜ, it indicates that the cloud-to-ground lightning voltage is within an acceptable range of the insulator, the degree of hazard is low, and no warning is required.

7. The low-amplitude direct lightning hazard assessment and warning method for the distribution network according to claim 1, wherein in Step 5, a warning level is directly proportional to the degree to which the overvoltage exceeds the lightning impulse withstand voltage.

8. The low-amplitude direct lightning hazard assessment and warning method for the distribution network according to claim 1, wherein the low-amplitude direct lightning hazard assessment and warning method is mainly used for low-amplitude lightning hazard assessment of the distribution networks, and a principle is also used for direct lightning hazard assessment of main network lines.
